(19) United States
(12) Patent Application Publication
(10) Pub. No.: US 2024/0175793 A1
(43) Pub. Date: May 30, 2024

(54) SPECIMEN INSERTION AND ALIGNMENT DEVICES, AND MATERIAL TESTING SYSTEMS INCLUDING SPECIMEN INSERTION AND ALIGNMENT DEVICES

(71) Applicant: Illinois Tool Works Inc., Glenview, IL (US)

(72) Inventors: Benjamin Hollander, Wayland, MA (US); Christopher Joyce, Braintree, MA (US)

(21) Appl. No.: 18/521,145

(22) Filed: Nov. 28, 2023

Related U.S. Application Data
(60) Provisional application No. 63/428,613, filed on Nov. 29, 2022.

(51) Int. Cl. G01N 3/12; G01N 3/06

(52) U.S. Cl. CPC G01N 3/12; G01N 3/06; G01N 2203/0017; G01N 2203/0411

(57) ABSTRACT

Disclosed example apparatus to align a test specimen in a universal testing system include: a first specimen grip configured to be attached to a universal testing system, to hold a test specimen in a first orientation with respect to the universal testing system, and to move the test specimen toward a test axis of the universal testing system; and a specimen stop configured to be attached to the universal testing system and to set a stop point of the test specimen, the first specimen grip and the specimen stop configured to align the test specimen with the test axis.

### RELATED APPLICATIONS

The present application claims the benefit of U.S. Patent Application Ser. No. 63/426,613, filed Nov. 29, 2022, entitled “SPECIMEN INSERTION AND ALIGNMENT DEVICES, AND MATERIAL TESTING SYSTEMS INCLUDING SPECIMEN INSERTION AND ALIGNMENT DEVICES.” The entirety of U.S. Patent Application Ser. No. 63/426,613 is expressly incorporated herein by reference.

### FIELD OF THE DISCLOSURE

This disclosure relates generally to mechanical testing, and more particularly, to specimen insertion and alignment devices, and material testing systems including specimen insertion and alignment devices.

### BACKGROUND

Universal testing machines are used to perform mechanical testing, such as compression strength testing or tension strength testing, on materials or components. Typically, a specimen is inserted into a load string, and forces are applied to the specimen by the universal testing machine, while a load cell or other sensor measures the forces. Testing may occur until specimen failure or other stopping point is reached.

### SUMMARY

Specimen insertion and alignment devices, and material testing systems including specimen insertion and alignment devices are disclosed, substantially as illustrated by and described in connection with at least one of the figures, as set forth more completely in the claims.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is an example testing device to perform mechanical property testing, in accordance with aspects of this disclosure.

FIG. 2 is a block diagram of an example implementation of the testing device of FIG. 1.

FIG. 3 is a perspective view of an example implementation of the test fixture and specimen insertion device of FIG. 2, in which the specimen insertion device has an arcuate path.

FIG. 4 is a perspective view of the example specimen insertion device of FIG. 3 in a first position.

FIG. 5 is a perspective view of the example specimen insertion device of FIG. 3 in a second position in which a specimen is in alignment with a test axis of the testing device.

FIG. 6 is a side elevation view of the example specimen insertion device of FIG. 3.

FIG. 7 is a top plan view of the example specimen insertion device of FIG. 3 in the first position.

FIGS. 8A and 8B illustrate top plan views of the example specimen insertion device of FIG. 2 in the second position for specimens having different widths.

FIG. 9 is a perspective view of another example implementation of the specimen insertion device of FIG. 2 in a first position, in which the specimen insertion device has a linear path.

FIG. 10 is a top plan view of the example specimen insertion device of FIG. 9 in the first position.

FIG. 11 is a front elevation view of the example specimen insertion device of FIG. 9 in the first position.

FIG. 12 is a side elevation view of the example specimen insertion device of FIG. 9.

FIGS. 13A, 13B, and 13C illustrate another example specimen grip that may be used to implement the specimen insertion device of FIG. 2.

FIGS. 14A, 14B, and 14C illustrate another example specimen grip and specimen stop that may be used to implement the specimen insertion device of FIG. 2.

The figures are not necessarily to scale. Wherever appropriate, similar or identical reference numerals are used to refer to similar or identical components.

### DETAILED DESCRIPTION

Conventional material testing systems require an operator to manually position a specimen while the fixturing of the material testing systems engage the specimen. For example, an operator may be required to hold the specimen with a first hand while controlling manual or powered grips with a second hand to engage the manually positioned specimen. Such techniques are subject to operator error than can result in invalid specimen tests and reduced throughput in a testing lab. In other cases, an operator may use static guides or stops that provide a limit on positioning of the specimen, but may still require the operator to at least partially manually position the specimen. Such guides or stops are intended for a specimen having specific dimensions, and changing specimen dimensions involves removal and replacement of the corresponding guides.

Disclosed example specimen insertion and alignment devices provide flexible and reliable specimen insertion and alignment with the load string for a range of specimen lengths, widths, and/or thicknesses. In disclosed examples, a specimen is inserted into a specimen grip by the operator, which can then be moved along a predetermined path into alignment with the test axis of the testing system. Disclosed example specimen insertion and alignment devices then hold the specimen in alignment with the test axis while the material fixturing of the testing system engages the specimen for testing.

The disclosed example specimen insertion and alignment devices allow for specimens of different dimensions to be inserted and properly aligned with no changes required by the operator. Additionally, disclosed example specimen insertion and alignment devices permit the operator to be completely clear of the load string and fixturing while the specimen is engaged by the fixturing.

As used herein, the “test axis” of a testing system or testing frame refers to an axis or a line along which the testing system applies a load to a specimen.

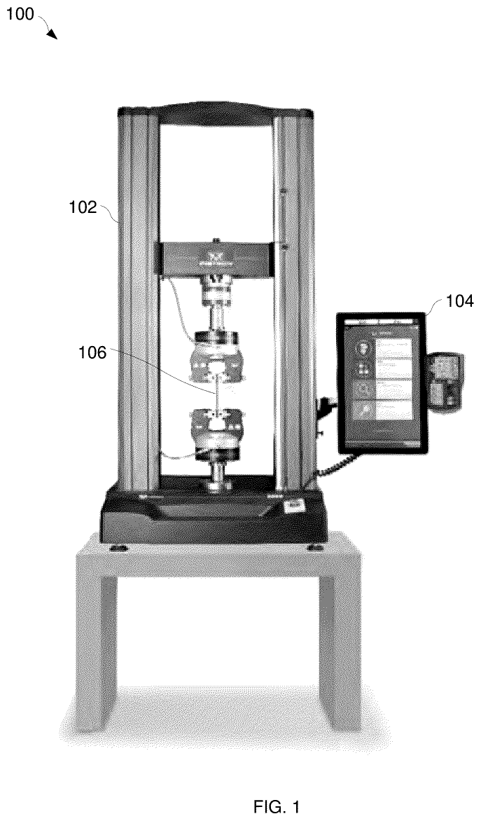

FIG. 1 is an example material testing system 100 to perform mechanical property testing. The example material testing system 100 may be, for example, a universal testing system capable of static mechanical testing. The material testing system 100 may perform, for example, compression strength testing, tension strength testing, shear strength testing, bend strength testing, deflection strength testing, tearing strength testing, peel strength testing (e.g., strength of an adhesive bond), and/or any other compressive, tensile, torsion, thermal, and/or impact testing. Additionally or alternatively, the material testing system 100 may perform dynamic testing.

The example material testing system 100 includes a test fixture 102 and a computing device 104 communicatively coupled to the test fixture 102. The test fixture 102 applies loads to a material under test 106 and measures the mechanical properties of the test, such as displacement of the material under test 106 and/or force applied to the material under test 106.

The example computing device 104 may be used to configure the test fixture 102, control the test fixture 102, and/or receive measurement results from the test fixture 102 for processing, display, reporting, and/or any other desired purposes.

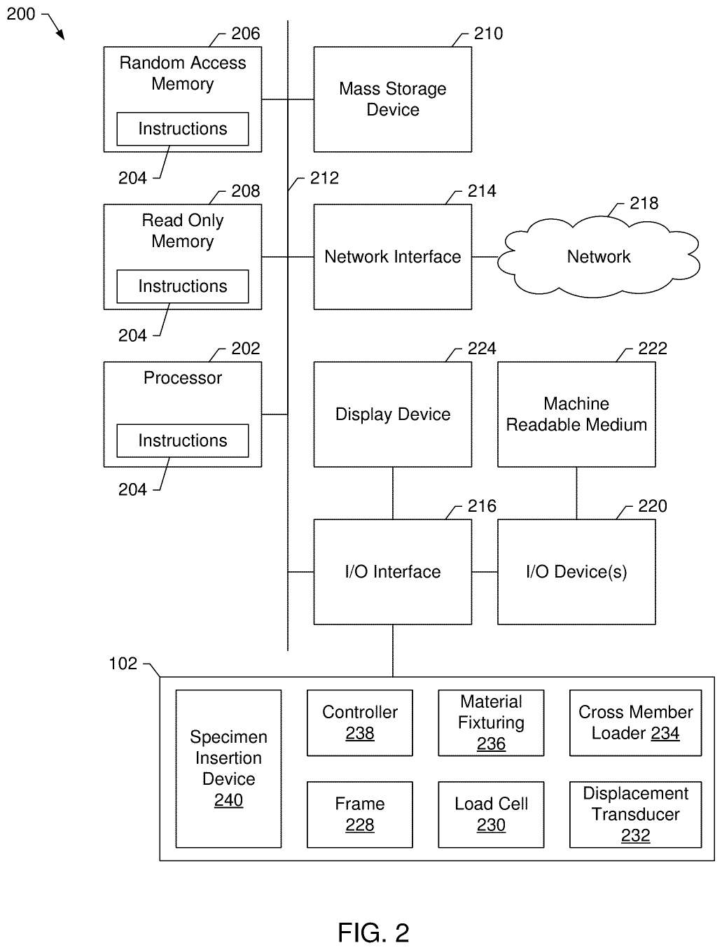

FIG. 2 is a block diagram of an example computing system 200 that may be used to implement the material testing system 100 of FIG. 1. The example material testing system 100 of FIG. 2 includes the test fixture 102 and the computing device 104. The example computing device 104 may be a general-purpose computer, a laptop computer, a tablet computer, a mobile device, a server, an all-in-one computer, and/or any other type of computing device.

The example computing system 200 of FIG. 2 includes a processor 202. The example processor 202 may be any general purpose central processing unit (CPU) from any manufacturer. In some other examples, the processor 202 may include one or more specialized processing units, such as RISC processors with an ARM core, graphic processing units, digital signal processors, and/or system-on-chips (SoC). The processor 202 executes machine readable instructions 204 that may be stored locally at the processor (e.g., in an included cache or SoC), in a random access memory 206 (or other volatile memory), in a read only memory 208 (or other non-volatile memory such as FLASH memory), and/or in a mass storage device 210. The example mass storage device 210 may be a hard drive, a solid state storage drive, a hybrid drive, a RAID array, and/or any other mass data storage device.

A bus 212 enables communications between the processor 202, the RAM 206, the ROM 208, the mass storage device 210, a network interface 214, and/or an input/output interface 216.

The example network interface 214 includes hardware, firmware, and/or software to connect the computing system 200 to a communications network 218 such as the Internet. For example, the network interface 214 may include IEEE 802.X-compliant wireless and/or wired communications hardware for transmitting and/or receiving communications.

The example I/O interface 216 of FIG. 2 includes hardware, firmware, and/or software to connect one or more input/output devices 220 to the processor 202 for providing input to the processor 202 and/or providing output from the processor 202. For example, the I/O interface 216 may include a graphics processing unit for interfacing with a display device, a universal serial bus port for interfacing with one or more USB-compliant devices, a FireWire, a field bus, and/or any other type of interface. The example material testing system 100 includes a display device 224 (e.g., an LCD screen) coupled to the I/O interface 216. Other example I/O device(s) 220 may include a keyboard, a keypad, a mouse, a trackball, a pointing device, a microphone, an audio speaker, a display device, an optical media drive, a multi-touch touch screen, a gesture recognition interface, a magnetic media drive, and/or any other type of input and/or output device.

The example computing system 200 may access a non-transitory machine readable medium 222 via the I/O interface 216 and/or the I/O device(s) 220. Examples of the machine readable medium 222 of FIG. 2 include optical discs (e.g., compact discs (CDs), digital versatile/video discs (DVDs), Blu-ray discs, etc.), magnetic media (e.g., floppy disks), portable storage media (e.g., portable flash drives, secure digital (SD) cards, etc.), and/or any other type of removable and/or installed machine readable media.

The example material testing system 100 of FIG. 1 further includes the test fixture 102 coupled to the computing system 200. In the example of FIG. 2, the test fixture 102 is coupled to the computing device via the I/O interface 216, such as via a USB port, a Thunderbolt port, a FireWire (IEEE 1394) port, and/or any other type serial or parallel data port. In some other examples, the test fixture 102 is coupled to the network interface 214 via a wired or wireless connection, either directly or via the network 218.

The test fixture 102 of FIG. 2 includes a frame 228, a load cell 230, a displacement transducer 232, a cross member loader 234, material fixtures 236, a controller 238, and sensor(s) 240. The test fixture 102 may include any number of other transducers, based on the type(s) of mechanical tests that the test fixture 102 is capable of performing. Other test fixtures may be dynamic test fixtures and/or include different test equipment, while including appropriate transducers that produce test data and may be controlled via the computing device 104. The example test fixture 102 may include actuators, load strings, fixturing, structural members, and/or any other components to facilitate compression strength testing, tension strength testing, shear strength testing, bend strength testing, deflection strength testing, tearing strength testing, peel strength testing (e.g., strength of an adhesive bond), and/or any other compressive, tensile, torsion, thermal, and/or impact testing, and/or dynamic testing.

The frame 228 provides rigid structural support for the other components of the test fixture 102 that perform the test. The load cell 230 measures force applied to a material under test by the cross member loader 234 (e.g., an electric motor, a hydraulic pump, a pneumatic actuator, and/or other actuator, which may be supported by a crosshead and/or other movable member(s) coupling the actuator to the specimen) via the material fixtures 236. The cross member loader 234 applies force to the material under test, while the material fixtures 236 (e.g., grips or other fixturing) grasp or otherwise couple the material under test to the cross member loader 234. Example material fixtures 236 include grips, jaws, jigs, anvils, compression platens, or other types of fixtures, depending on the mechanical property being tested and/or the material under test.

The example controller 238 communicates with the computing device 104 to, for example, receive test parameters from the computing device 104 and/or report measurements and/or other results to the computing device 104. For example, the controller 238 may include one or more communication or I/O interfaces to enable communication with the computing device 104. The controller 238 may control the cross member loader 234 to increase or decrease applied force, control the fixture(s) 236 to grasp or release a material under test, and/or receive measurements from the displacement transducer 232, the load cell 230, and/or any other transducer(s).

The example test fixture 102 may further include a specimen insertion device 240. The specimen insertion device 240 may be attached to the test fixture 102 for stability and/or repeatability, and improves the consistency and reliability of specimen insertion and testing. As disclosed in more detail below, the specimen insertion device 240 permits an operator or automated system to place a specimen into the specimen insertion device 240, and then insert the specimen insertion device 240 into position for the material fixtures 236 (e.g., grips) to grip the specimen such that the specimen is in alignment with the test axis.

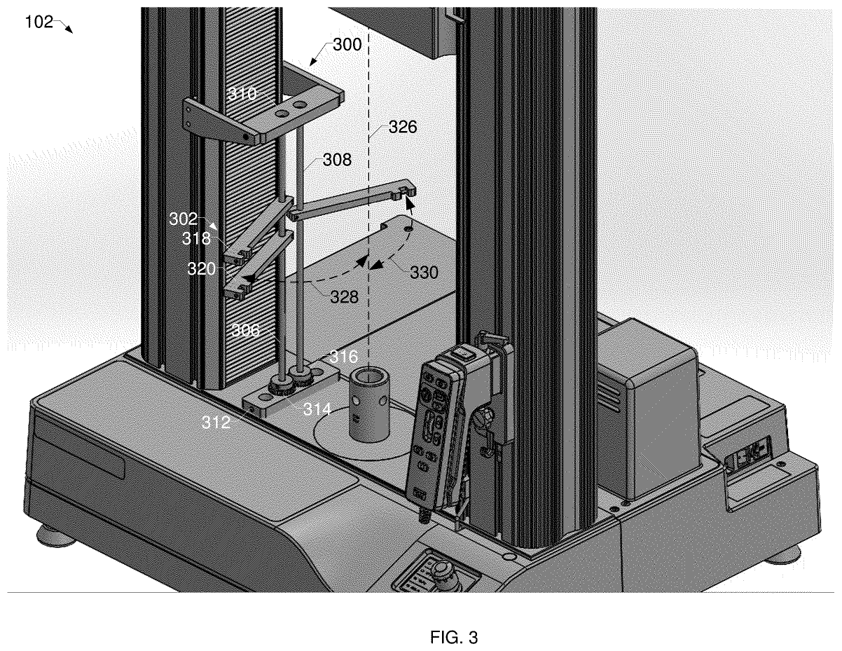

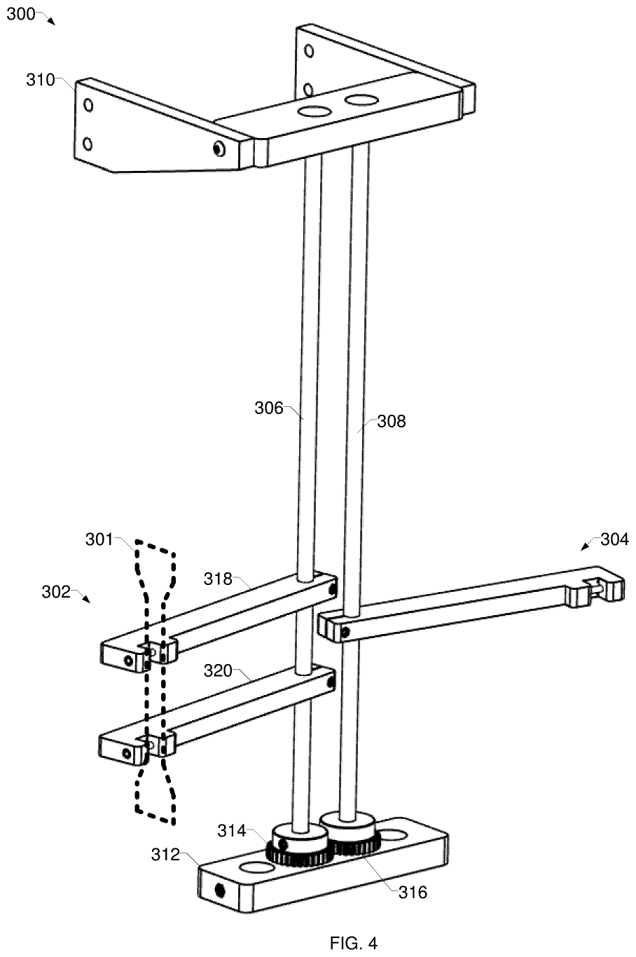

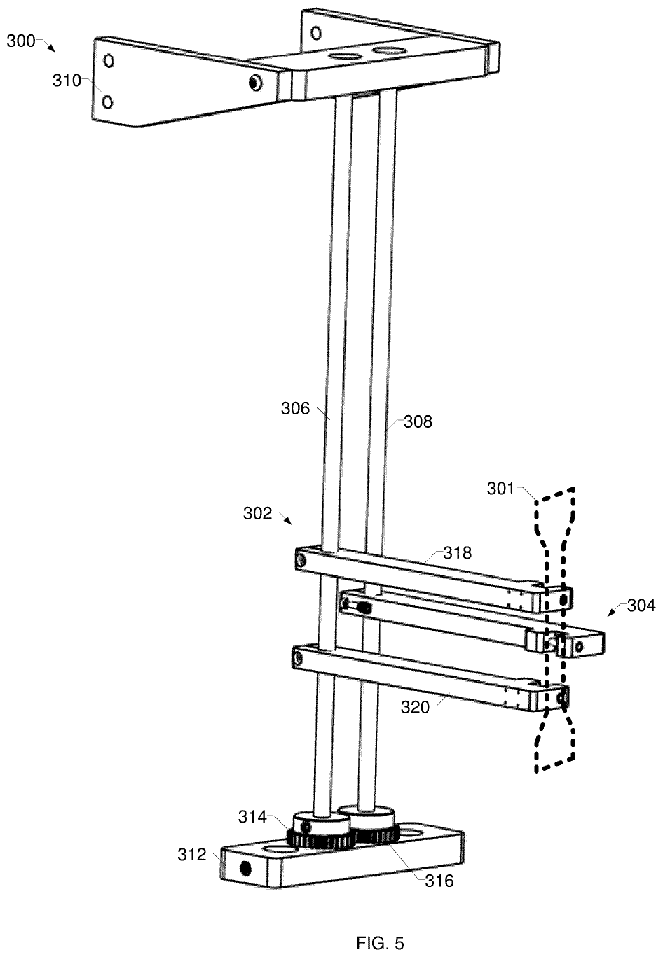

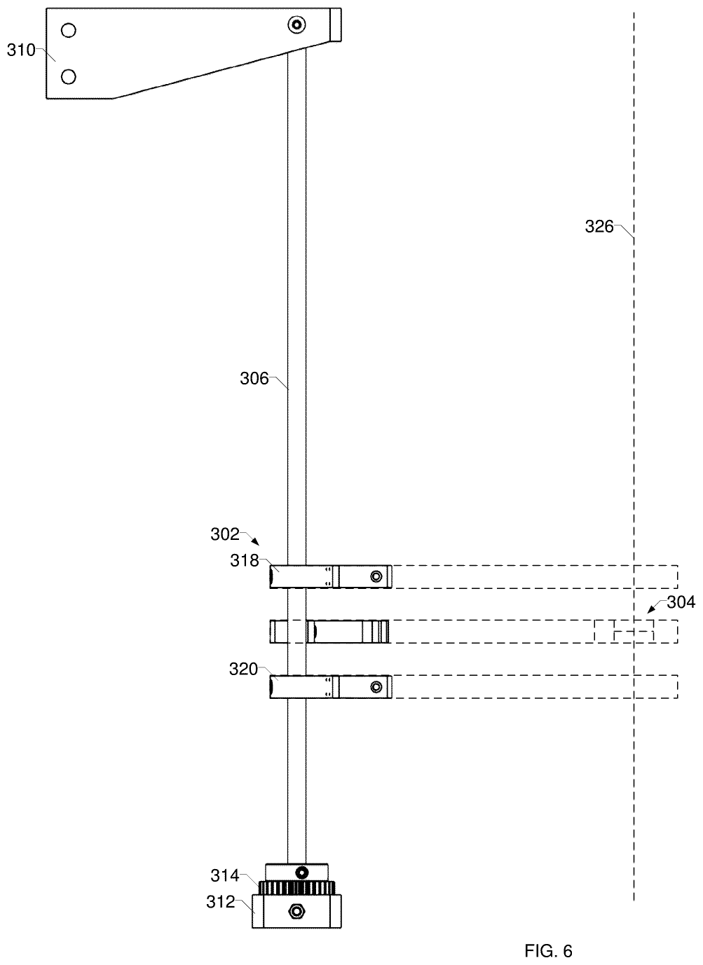

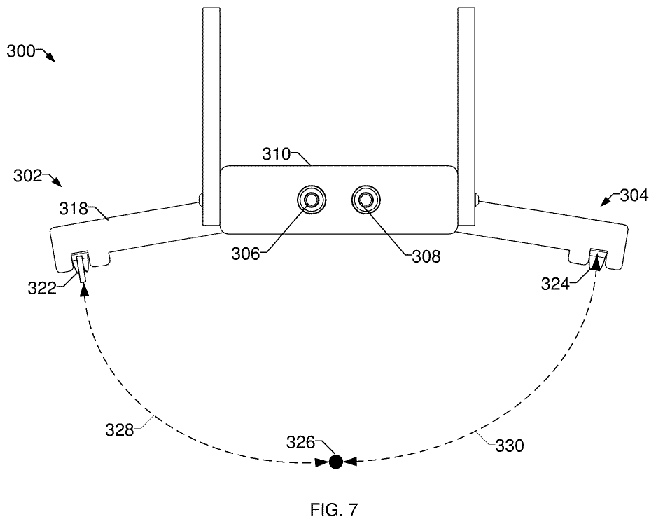

FIG. 3 is a perspective view of an example implementation of a test fixture 102 and a specimen insertion device 300 that may be used to implement the specimen insertion device 240 of FIG. 2 to position a specimen 301 in the test fixture 102. FIG. 4 is a perspective view of the example specimen insertion device 300 of FIG. 3 in a first position. FIG. 5 is a perspective view of the example specimen insertion device 300 of FIG. 3 in a second position in which a specimen is in alignment with a test axis of the testing device. FIG. 6 is a side elevation view of the example specimen insertion device 300 of FIG. 3. FIG. 7 is a top plan view of the example specimen insertion device 300 of FIG. 3 in the first position.

The example specimen insertion device 300 includes a first specimen grip 302 and a specimen stop 304. The specimen grip 302 and the specimen stop 304 are each coupled to a respective dowel 306, 308 for rotation of the specimen grip 302 and the specimen stop 304. The dowels 306, 308 are coupled to the frame 228 (e.g., a stationary leg of the frame 228) to secure the rotational axes of the specimen grip 302 and the specimen stop 304 in a stationary position with respect to the frame 228. The example dowels 306, 308 may be keyed or have non-circular cross-sections (e.g., square, hexagonal) to provide consistent relative rotation of the specimen grip 302 and the specimen stop 304, and/or to define the alignment of the arms of the specimen grip 302 and the specimen stop 304.

The dowels 306, 308 are is attached or otherwise secured to the frame 228 of the test fixture 102 via an upper bracket 310 and a lower bracket 312. The brackets 310, 312 permit the dowels 306, 308 to rotate but hold the dowels in a stationary position with respect to the frame 228. In other examples, the specimen grip 302 and/or the specimen stop 304 may be mounted to other portions of the test frame 228, such as to the cross member loader 234 and/or a base of the test fixture 102 to enable adjustment of the height of the specimen grip 302 and the specimen stop 304. In still other examples, the specimen grip 302 and/or the specimen stop 304 may be mounted to other structures which are stationary with respect to the test fixture 102, such as a support surface (e.g., a floor, a table, etc.), a stationary lateral surface (e.g., a nearby wall), and/or to a device which is removably installed on the test fixture 102 (e.g., attached or mounted to removable material fixturing 236, such as a removable grip).

The example dowels 306, 308 of FIG. 3 are geared to provide control of the rotation. In the illustrated example, the gears 314, 316 of the dowels 306, 308 are rotationally coupled to provide simultaneous and opposing rotation from a first (e.g., open, or non-aligned) position to a second (e.g., closed, test axis-aligned) position.

An actuator may actuate the pinion gear to cause the specimen grip 302 and the specimen stop 304 to move inwardly (e.g., towards one another and/or towards the test axis 326) or outwardly (e.g., away from one another and/or away from the test axis 326) via the gears 314, 316 and the dowels 306, 308. Additionally or alternatively, either the specimen grip 302 or the specimen stop 304 may be manually actuated (e.g., pushed or pulled by an operator), which results in the simultaneous actuation of the other of the specimen grip 302 or the specimen stop 304 in the opposing direction.

The example specimen grip 302 holds a test specimen in a first orientation with respect to the frame 228. For example, the specimen grip 302 includes a first arm 318 and a second arm 320. The example first arm 318 includes a first spring clip 322, and the second arm includes a second spring clip 324. The spring clips 322, 324 allow for easy insertion of specimens into the specimen grip 302, sufficient holding strength to retain the specimen during positioning, and sufficiently low holding strength to release the specimen when the specimen is held in place by the grips. However, other specimen retention techniques may be used, such as a spring loaded clamp, one or more ball plungers, electrically controlled clamp(s) (e.g., electromagnetic relays) and/or any other retention devices. Additionally or alternatively, the specimen grip 302 may be configured to hold a fixture for a non-rigid specimen such that the non-rigid specimen can be aligned into the test axis 326 in a similar manner as a rigid specimen. For example, the fixture for a non-rigid specimen may be designed to hold the non-rigid specimen in the desired position when attached (e.g., magnetically coupled) to the specimen grip 302.

In some examples, the arms 318, 320 may be replaceable and/or modifiable with arms configured to hold or retain a specific geometry of specimen. For example, the arms 318, 320 may be removed from the dowel 306 and replaced with arms 318, 320 having a different retention geometry and/or retention feature(s).

The first arm 318 is aligned with the second arm 320, and the first spring clip 322 is aligned with the second spring clip 324, along the axis of rotation of the specimen grip 306 (e.g., in the direction of the dowel 306). The specimen may be inserted into the first and second arms 318, 320 by pushing the specimen into the spring clips 322, 324 until the specimen reaches a stop surface of each arm 318, 320, at which point the specimen is aligned in a same direction as a test axis 326 of the test frame 102.

Following insertion of the specimen into the specimen grip 302, the specimen grip 302 and the specimen stop 304 are rotated (e.g., along a predetermined arcuate path 328) to place the specimen into alignment with the test axis 326. The specimen grip 302 is rotated along the predetermined arcuate path 328 until the specimen makes contact with the specimen stop 304, which is rotating along a second predetermined arcuate path 330 in an opposing direction as the specimen grip 302. The example specimen stop 304 is configured to make contact with the specimen 301 at a location between the points at which the arms 318, 320 grip the specimen 301 (e.g., along a lengthwise direction of the specimen 301). At the point at which the specimen is fully engaged with both the specimen grip 302 and the specimen stop 304 (e.g., further rotation is blocked), the specimen is aligned with the test axis 326 and is in position to be engaged by the material fixtures 236.

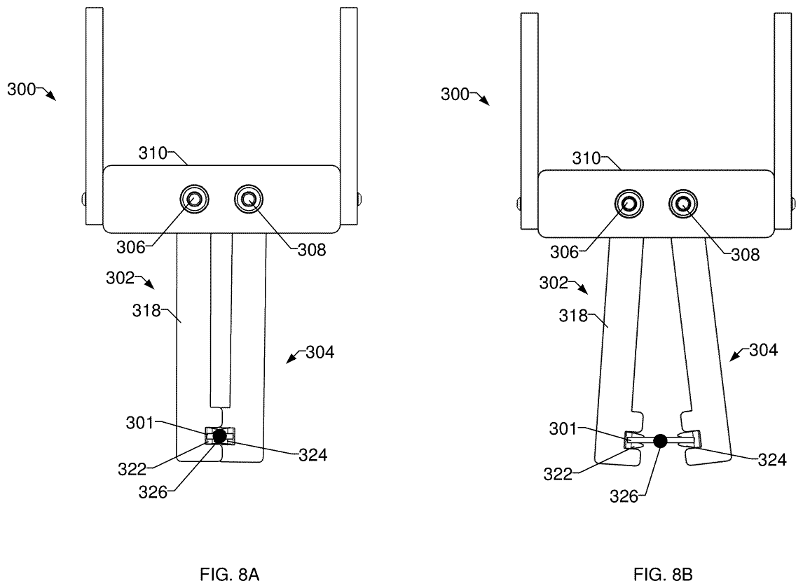

The example specimen grip 302 and the specimen stop 304 are able to align specimens have a range of heights (or lengths), a range of widths, and/or a range of thicknesses with the test axis 326. FIGS. 8A and 8B illustrate top plan views of the example specimen insertion device 300 of FIG. 2 in the second position for specimens having different widths. As illustrated in FIGS. 8A and 8B, the specimen grip 302 may travel farther along the arcuate path 328 prior to the specimen 301 contacting the specimen stop 304 for narrower specimens than for wider specimens.

When the specimen is engaged (e.g., gripped) by the material fixtures 236, the specimen may be released by the specimen grip 302 by moving the specimen grip 302 (and the specimen stop 304) away from the test axis 326.

While the example specimen grip 302 of FIG. 3 includes multiple arms, in other examples the specimen grip 302 may include a single arm that includes forked clips and/or stopping points, and/or a wider clip that reduces or prevents rotation of the specimen within the specimen grip 302.

Instead of an arm, the specimen stop 304 may include one or more stationary surfaces positioned to abut the specimen when the specimen is moved into alignment with the test axis 326. For example, a surface (e.g., a rod, etc.) may be positioned adjacent the test axis 326 at a distance that is selected to abut the specimen when the desired positioning and alignment are achieved. The specimen stop 304 may be adjustable for different specimen widths, and secured to provide consistent positioning of the specimen in alignment with the test axis 326.

While the example specimen grip 302 and the specimen stop 304 have axes of rotation that are parallel to the test axis 326, in other examples one or both of the specimen grip 302 and the specimen stop 304 may have different axes of rotation defining the predetermined arcuate path of movement toward the test axis 326.

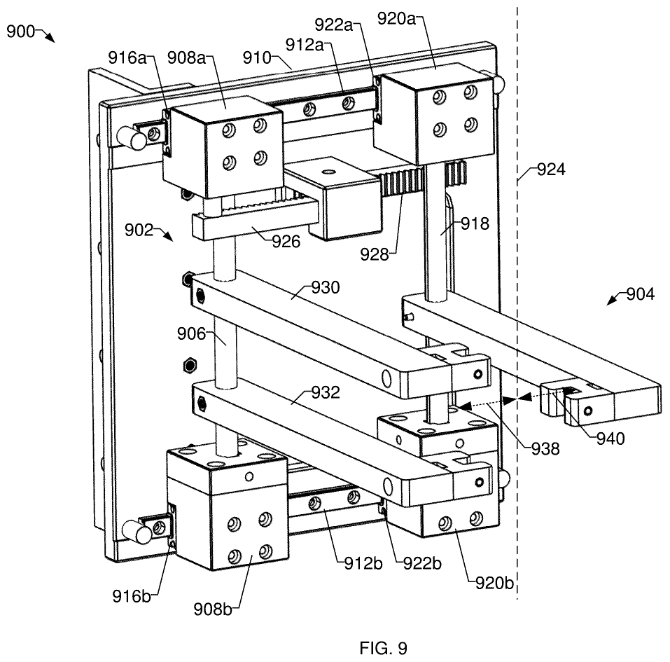

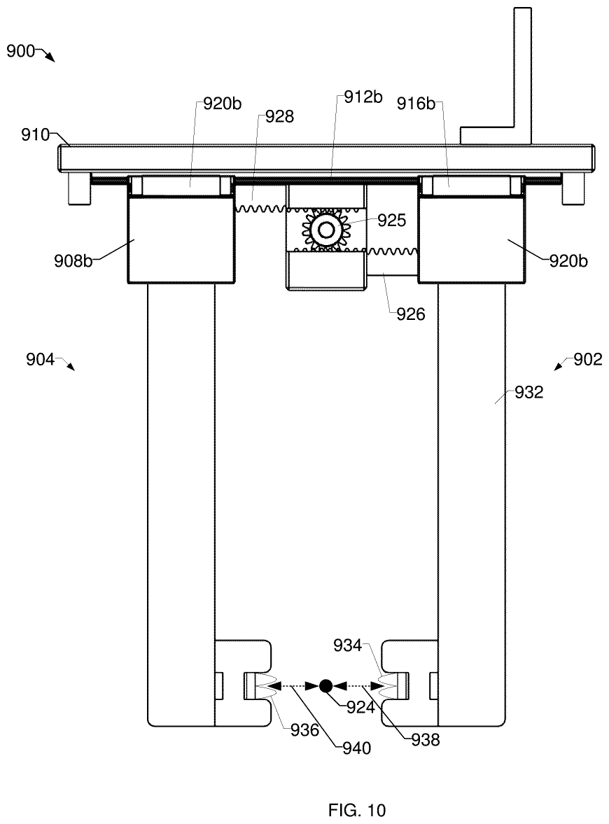

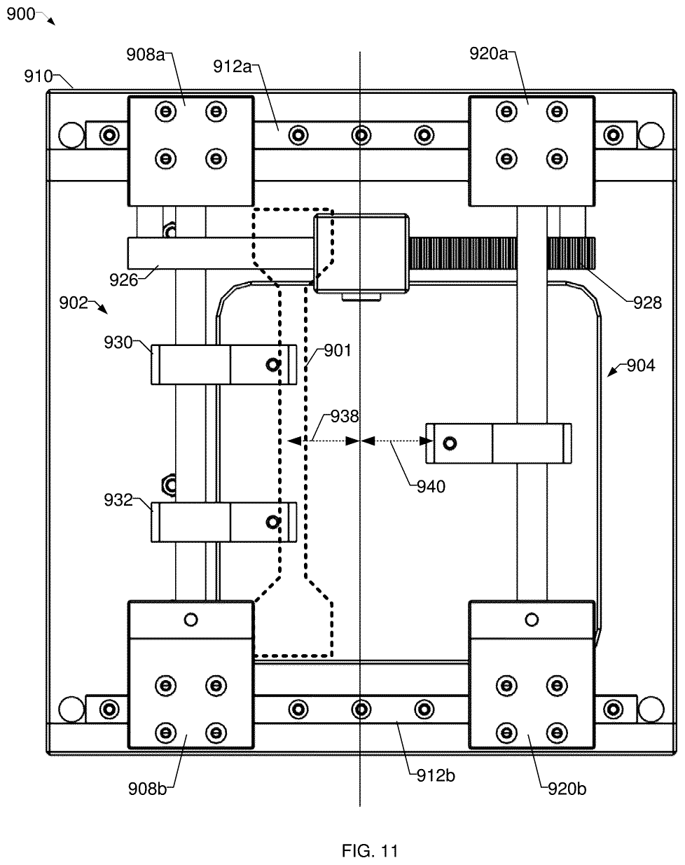

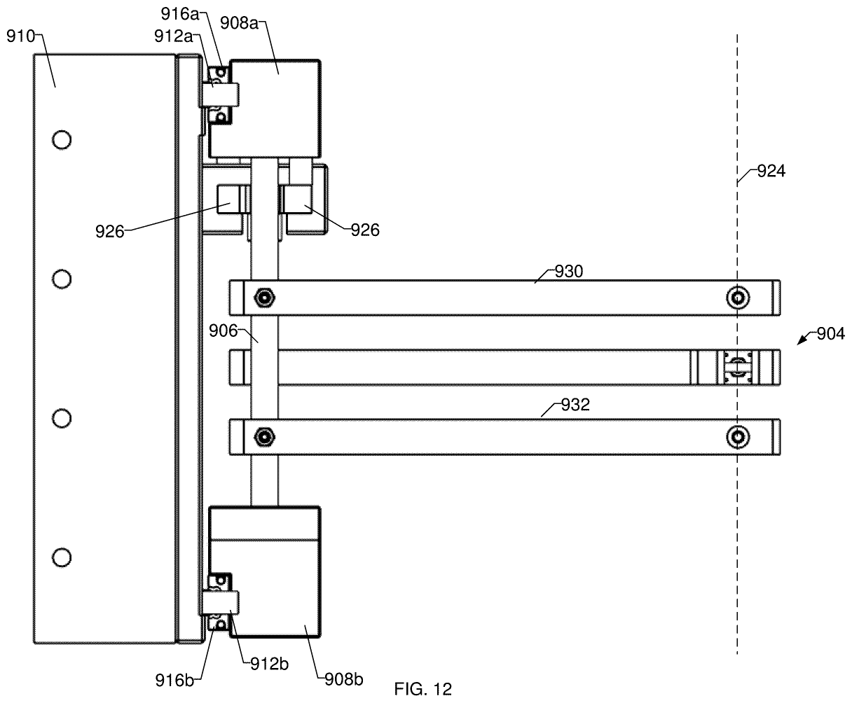

FIG. 9 is a perspective view of another example specimen insertion device 900 that may be used to implement the specimen insertion device 240 of FIG. 2. In contrast with the example specimen insertion device 300 of FIG. 3, the specimen insertion device 900 moves a specimen 901 between a first (e.g., open, or non-aligned) position and a second (e.g., closed, test axis-aligned) position along a linear path instead of an arcuate path. FIG. 10 is a bottom plan view of the example specimen insertion device 900 of FIG. 9 in the first position. FIG. 11 is a front elevation view of the example specimen insertion device 900 of FIG. 9 in the first position. FIG. 12 is a side elevation view of the example specimen insertion device 900 of FIG. 9. The example specimen insertion device 900 may avoid interference between specimens and material fixturing (e.g., grip faces) that could occur with relatively wide specimens and closely-spaced grip faces when using arcuate paths for insertion of the specimen.

The example specimen insertion device 900 includes a specimen grip 902 and a specimen stop 904. The specimen grip 902 is attached to a dowel 906, which may be keyed and/or have other alignment features to provide the correct alignment of the specimen grip 902 with respect to the travel path. The dowel 906 is supported by mounting blocks 908a, 908b, which are attached to a frame 910 via rails 912a, 912b which extend parallel to a linear travel path 914 of the specimen 901. The mounting blocks 908a, 908b are coupled to the rails 912a, 912b via bearings 916a, 916b. The frame 910 may be attached to the test fixture 102 in a similar manner as the specimen insertion device 300 of FIG. 3, and/or via another method. For example, the specimen grip 902 and/or the specimen stop 904 may be mounted to other portions of the test frame 228, such as to the cross member loader 234 and/or a base of the test fixture 102 to enable adjustment of the height of the specimen grip 902 and the specimen stop 904.

Similarly, the specimen stop 904 is attached to a dowel 918, which may be keyed and/or have other alignment features to provide the correct alignment of the specimen grip 902 with respect to the travel path. The dowel 918 is supported by mounting blocks 920a, 920b, which are attached to the frame 910 via the rails 912a, 912b. The mounting blocks 920a, 920b are coupled to the rails 912a, 912b via bearings 922a, 922b.

The frame 910 is stationary with respect to the test frame 102, and the specimen grip 902 moves the test specimen 901 toward a test axis 924 of the test frame 102. The specimen stop 904 sets a stop point of the test specimen 901, such that the specimen grip 902 and the specimen stop 904 align the test specimen 901 with the test axis 924.

In the example of FIG. 9, the specimen grip 902 is mechanically coupled to the specimen stop 904 such that the specimen grip 902 and the specimen stop 904 are simultaneously actuated in opposing linear directions. For example, the mounting blocks 908a and 920a are coupled via a pinion gear 925 and opposing rack gears 926, 928. An actuator may actuate the pinion gear to cause the specimen grip 902 and the specimen stop 904 to move inwardly (e.g., towards one another and/or towards the test axis 924) or outwardly (e.g., away from one another and/or away from the test axis 924) via the mounting blocks 908a and 920a and the dowels 906, 918. Additionally or alternatively, either the specimen grip 902 or the specimen stop 904 may be manually actuated (e.g., pushed or pulled by an operator), which results in the simultaneous actuation of the other of the specimen grip 902 or the specimen stop 904 in the opposing direction.

The example dowels 906, 918 may be configured to rotate within the mounting blocks 908a, 908b, 920a, 920b to make the specimen grip 902 more accessible for insertion and/or removal of the specimen 901. The dowels 906, 918, the mounting blocks 908a, 908b, and/or the mounting blocks 920a, 920b may include ball detents, other types of detents, and/or other types of position retention devices to hold the dowels 906, 918 in a desired angular position (e.g., an open position, a closed position). The rotation of the dowels 906, 918 may be independent to allow for unlinked rotation, or geared to provide simultaneous rotation.

The example specimen grip 902 retains the specimen 901 via arms 930, 932 which are coupled to, and extend from, the dowel 906. The example first arm 930 includes a first spring clip 934, and the second arm 932 includes a second spring clip 936. The spring clips 934, 936 allow for easy insertion of specimens 901 into the specimen grip 902, sufficient holding strength to retain the specimen 901 during positioning, and sufficiently low holding strength to release the specimen 901 when the specimen 901 is held in place by the grips. The example specimen stop 904 is configured to make contact with the specimen 901 at a location between the points at which the arms 930, 932 grip the specimen 901 (e.g., along a lengthwise direction of the specimen 901).

The arms 930, 932 are aligned along the dowel 906, and hold the specimen 901 parallel with the test axis 924. In some examples, the arms 930, 932 may be replaceable and/or modifiable with arms configured to hold or retain a specific geometry of specimen. For example, the arms 930, 932 may be removed from the dowel 906 and replaced with arms 930, 932 having a different retention geometry and/or retention feature(s).

Following insertion of the specimen 901 into the specimen grip 902, the specimen grip 902 and the specimen stop 904 are translated to place the specimen 902 into alignment with the test axis 924. The specimen grip 902 is translated along a predetermined linear path 938 until the specimen 901 makes contact with the specimen stop 904, which is rotating along a second predetermined linear path 940 in an opposing direction as the specimen grip 902. At the point at which the specimen 902 is fully engaged with both the specimen grip 902 and the specimen stop 904 (e.g., further translation is blocked), the specimen 901 is aligned with the test axis 924 and is in position to be engaged by the material fixtures 236.

By enabling the dowels 906, 918 and/or the arms 930, 932 to rotate, the predetermined paths may be partially arcuate (e.g., rotating the arms 930, 932 from a loading position in which the specimen 901 held by the specimen grip 902 is not aligned with the test axis 924, to a closed position in which the specimen 901 is aligned with the test axis 924) and partially linear (e.g., translating the aligned specimen 901 along a linear path into alignment with the test axis 924).

When the specimen is engaged (e.g., gripped) by the material fixtures 236, the specimen may be released by the specimen grip 902 by moving the specimen grip 902 (and the specimen stop 904) away from the test axis 924.

In some other examples, sliding or low-friction surfaces may alternatively be used in place of the bearings 916a, 916b, 922a, 922b.

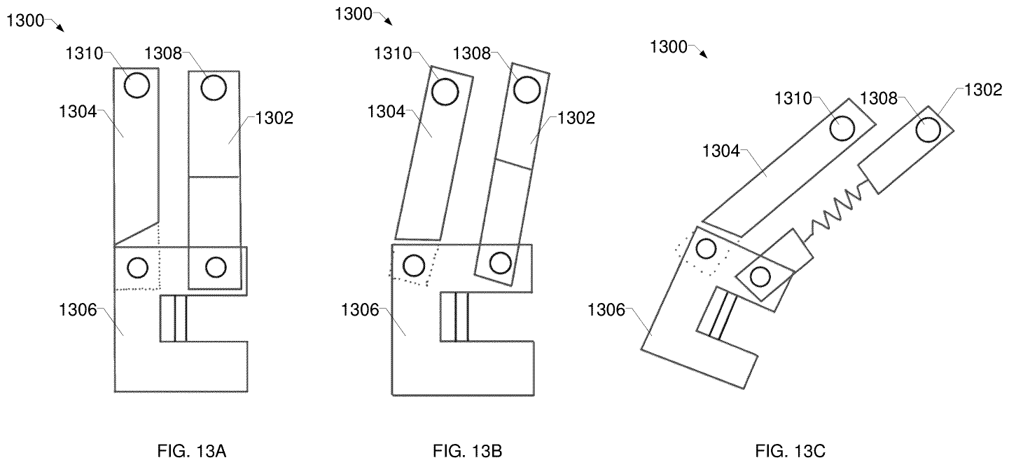

FIGS. 13A, 13B, and 13C illustrate another example specimen grip 1300 that may be used to implement the specimen insertion device 240 of FIG. 2. For example, the specimen grip 1300 may replace the specimen grip 302 of FIG. 3. The specimen grip 1300 may be implemented in conjunction with a specimen stop having an opposing motion and/or pathway, and/or a static specimen stop. The example specimen grip 1300 may avoid interference between specimens and material fixturing (e.g., grip faces) that could occur with relatively wide specimens and closely-spaced grip faces when using arcuate paths for insertion of the specimen.

FIG. 13A illustrates the specimen grip 1300 in a closed position, in which a specimen held by the specimen grip 1300 is aligned with a test axis. The specimen grip 1300 includes a separable linkage 1302 and a non-separable linkage 1304. The separable linkage 1302 rotationally couples a jaw 1306 of the specimen grip 1300 to a first mounting point 1308 coupled to the test frame 102. Similarly, the non-separable linkage 1304 rotationally couples the jaw 1306 to a second mounting point 1310 coupled to the test frame 102.

The portion of the movement path of the specimen grip 1300 that is closest to the test axis (FIG. 13A to 13B) is substantially linear due to the movement of the linkages 1302, 1304. As the specimen grip 1300 moves farther from the test axis (FIG. 13B to 13C), the separable linkage 1302 separates and extends to allow for continued movement of the jaw 1306 as well as rotation of the jaw 1306 (e.g., to receive and/or remove a specimen from the jaw 1306).

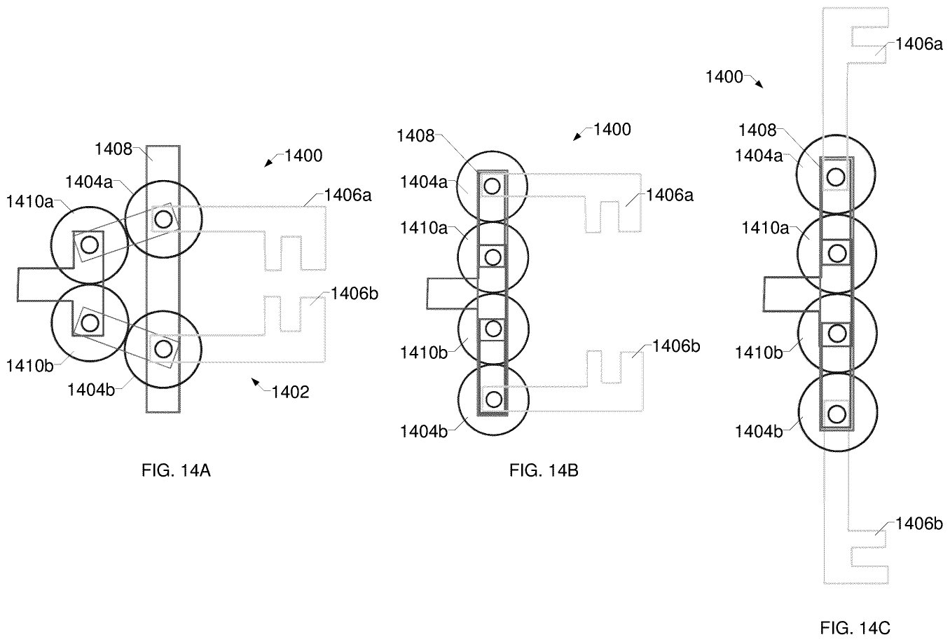

FIGS. 14A, 14B, and 14C illustrate another example specimen grip 1400 and specimen stop 1402 that may be used to implement the specimen insertion device 240 of FIG. 2. For example, the specimen grip 1400 and specimen stop 1402 may replace the specimen grip 302 and specimen stop 304 of FIG. 3. The example specimen grip 1400 and specimen stop 1402 may avoid interference between specimens and material fixturing (e.g., grip faces) that could occur with relatively wide specimens and closely-spaced grip faces when using arcuate paths for insertion of the specimen.

The specimen grip 1400 and specimen stop 1402 includes translating gears 1404a, 1404b, respectively, that are coupled to respective arms 1406a, 1406b. Movement of the arms 1406a, 1406b in the portion of the predetermined pathway closest to the test axis causes linear motion separate from arm rotation by forcing the gears 1404a, 1404b along a linear pathway 1408 via gears 1410a, 1410b. When the gears 1404a, 1404b reach the distal ends of the linear pathway 1408, the gears 1404a, 1404b then rotate the arms 1406a, 1406b.

In some examples, the specimen grip and/or specimen stop may include handles, knobs, or other features to improve operator grip, such as on the arms, mounting blocks, and/or other features of the specimen grip and/or specimen stop.

In some examples, the arms of the specimen grip and/or specimen stop have predetermined positions and/or predetermined relationships. For example, the arms 318, 320 may be geared such that the arms 318, 320 move toward or away from each other simultaneously and/or are consistently equidistant from a same point along the dowel 306.

Additionally or alternatively, the dowels 306, 308 and/or the gears 314, 316 may have predetermined positions along the paths 328, 330 at which the specimen grip 302 and/or the specimen stop 304 may be set or fixed. For example, the dowels 306, 308 and/or the gears 314, 316 may have a detent to hold the specimen grip 302 and/or the specimen stop 304 in an open (e.g., specimen loading) position.

In some examples, the testing system 100 may be provided with physical barriers or shields to reduce or prevent encroachment of an operator's hands and/or other objects into the load string. Such physical barriers or shields may be provided with cutouts, gaps, apertures, or other spaces through which a specimen insertion device as disclosed herein, and a specimen held by the specimen insertion device, can pass through the barrier to be inserted into the testing system.

In some examples, an actuator that controls the specimen insertion devices 300, 900 may be controlled by software that controls the testing system 100. For example, the testing system 100 may include software that 1) controls the specimen insertion device 300, 900 to move a held specimen into alignment with the test axis 326, 924; 2) controls the fixturing 236 to grip the specimen; 3) controls the specimen insertion device 300, 900 to move away from the test axis 326, 924; and 4) controls the testing system to apply the load to the specimen and measure displacement, load, and/or any other desired parameters.

In some examples, the material testing system 100 may include one or more sensors to determine position(s) of the specimen grip 302, 902 and/or the specimen stop 304, 904. For example, the sensors may include proximity sensors or switches to determine whether the specimen grip 302, 902 and/or the specimen stop 304, 904 are in a particular position, and/or an encoder or other position sensors to determine a position of the specimen grip 302, 902 and/or the specimen stop 304, 904 along a corresponding predetermined path. The controller of the material testing system 100 may control a test sequence based on the position of the specimen grip 302, 902 and/or the specimen stop 304, 904, such as by actuating material fixturing when the specimen grip 302, 902 and/or the specimen stop 304, 904 are in a closed position.

In some examples, the material testing system 100 may include one or more sensors to determine whether a specimen is loaded into the specimen insertion device. For example, the material testing system may include a contact sensor to determine whether a specimen is held by the clips or other holding devices in the specimen grip 302, 902, and/or any other type of sensor to determine the presence of a specimen in the specimen insertion device. The controller of the material testing system 100 may trigger initiation of a testing or measurement procedure based on the presence of a specimen.

In some examples, the material testing system 100 may include one or more sensors to determine whether an operator is manipulating or otherwise holding the specimen grip 302, 902 and/or the specimen stop 304, 904. For example, the controller of the material testing system 100 may halt actuation of the material fixturing and/or other actuators of the material testing system 100 in response to determining that an operator is in contact with the specimen insertion device.

The present methods and systems may be realized in hardware, software, and/or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may include a general-purpose computing system with a program or other code that, when being loaded and executed, controls the computing system such that it carries out the methods described herein. Another typical implementation may comprise an application specific integrated circuit or chip. Some implementations may comprise a non-transitory machine-readable (e.g., computer readable) medium (e.g., FLASH drive, optical disk, magnetic storage disk, or the like) having stored thereon one or more lines of code executable by a machine, thereby causing the machine to perform processes as described herein. As used herein, the term “non-transitory machine-readable medium” is defined to include all types of machine readable storage media and to exclude propagating signals.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. For example, block and/or components of disclosed examples may be combined, divided, re-arranged, and/or otherwise modified. In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

1. An apparatus to align a test specimen in a universal testing system, the apparatus comprising:
a first specimen grip configured to be attached to a universal testing system, to hold a test specimen in a first orientation with respect to the universal testing system, and to move the test specimen toward a test axis of the universal testing system; and
a specimen stop configured to be attached to the universal testing system and to set a stop point of the test specimen, the first specimen grip and the specimen stop configured to align the test specimen with the test axis.

2. The apparatus as defined in claim 1, wherein the first specimen grip is configured to move the test specimen along a predetermined path toward and away from the test axis.

3. The apparatus as defined in claim 2, wherein the specimen stop is configured to move toward and away from the test axis along a second predetermined path.

4. The apparatus as defined in claim 3, wherein the specimen stop and the first specimen grip are linked to move toward the test axis simultaneously and to move away from the test axis simultaneously.

5. The apparatus as defined in claim 2, wherein the predetermined path is at least partially an arcuate path.

6. The apparatus as defined in claim 2, wherein the predetermined path is at least partially a linear path.

7. The apparatus as defined in claim 1, wherein the first specimen grip comprises first and second retention devices configured to hold the test specimen at first and second points.

8. The apparatus as defined in claim 7, wherein the specimen stop is configured to make contact with the test specimen at a location that is between the first and second points along a length of the test specimen.

9. The apparatus as defined in claim 7, wherein the first and second retention devices and the specimen stop are configured to align test specimens having a range of heights, a range of widths, and a range of thicknesses, with the test axis.

10. The apparatus as defined in claim 1, further comprising an actuator configured to actuate the first specimen grip to move the test specimen toward the test axis.

11. The apparatus as defined in claim 1, wherein the first specimen grip is configured to hold the test specimen at a predetermined fixed height with respect to the test axis.

12. The apparatus as defined in claim 1, wherein a position of at least one of the first specimen grip or the specimen stop are adjustable along a length of the test specimen.

13. A material testing system, comprising:
a test frame;
a crosshead coupled to the test frame;
grips coupled to the crosshead and configured to hold a test specimen;
an actuator configured to actuate the crosshead along a test axis to apply force to the test specimen along the test axis via the grips;
a first specimen grip coupled to the test frame, and configured to hold the test specimen in a first orientation with respect to the universal testing system and to move the test specimen toward a test axis of the universal testing system; and
a specimen stop coupled to the test frame and to set a stop point of the test specimen, the first specimen grip and the specimen stop configured to align the test specimen with the test axis.

14. The material testing system as set forth in claim 13, wherein the first specimen grip is configured to move the test specimen along a predetermined path toward and away from the test axis.

15. The material testing system as set forth in claim 14, wherein the specimen stop is configured to move toward and away from the test axis along a second predetermined path.

16. The material testing system as set forth in claim 15, wherein the specimen stop and the first specimen grip are linked to move toward the test axis simultaneously and to move away from the test axis simultaneously.

17. The material testing system as set forth in claim 16, further comprising a second actuator configured to actuate the first specimen grip and the specimen stop.

18. The material testing system as set forth in claim 14, wherein the predetermined path is at least partially a linear path.

19. The material testing system as set forth in claim 14, wherein the predetermined path is at least partially an arcuate path.

20. The material testing system as set forth in claim 13, wherein the first specimen grip and the specimen stop are configured to align test specimens having a range of heights, a range of widths, and a range of thicknesses, with the test axis.
